(19) United States
(12) Patent Application Publication
(10) Pub. No.: US 2020/0123676 A1
(43) Pub. Date: Apr. 23, 2020

(54) QUARTZ GLASS CRUCIBLE

(71) Applicant: SUMCO CORPORATION, Minato-ku, Tokyo (JP)

(72) Inventors: Takuma YOSHIOKA, Akita-shi (JP); Masami OHARA, Akita-shi (JP)

(21) Appl. No.: 16/622,179

(22) PCT Filed: Jun. 11, 2018
(86) PCT No.: PCT/JP2018/022226

§ 371 Date: Dec. 12, 2019

(30) Foreign Application Priority Data
Jul. 4, 2017 (JP) 2017-131408

(51) Int. Cl. C30B 15/10; C30B 29/06

(52) U.S. Cl. CPC C30B 15/10; C30B 29/06

(57) ABSTRACT

In an exemplary embodiment, a quartz glass crucible 1 includes: a straight body portion 1a having a cylindrical shape; a bottom portion 1b; and a corner portion 1c, in which a bubble content of an inner surface layer portion ranging from an inner surface to a depth 0.5 mm in an upper portion 1a₁ of the straight body portion 1a is 0.2% to 2%, the bubble content of the inner surface layer portion in a lower portion 1a₂ of the straight body portion 1a is more than 0.1% and not more than 1.3 times a lower limit of the bubble content of the upper portion 1a₁, the bubble content of the inner surface layer portion in the corner portion 1c is more than 0.1% and 0.5% or less, and the bubble content of the inner surface layer portion in the bottom portion 1b is 0.1% or less.

### TECHNICAL FIELD

The present invention relates to a quartz glass crucible and, particularly to a quartz glass crucible used for pulling up a silicon single crystal by the Czochralski method (CZ method).

### BACKGROUND ART

A quartz glass crucible is used for manufacturing a silicon single crystal by the CZ method. In the CZ method, a silicon raw material is heated in the quartz glass crucible to be melted, a seed crystal is dipped into the silicon melt, and then the seed crystal is gradually pulled up while rotating the crucible to grow a single crystal. In order to manufacture a high-quality silicon single crystal for a semiconductor device at low costs, it is necessary to increase the manufacturing yield of silicon single crystals without dislocations and defects.

During a step of pulling up a silicon single crystal, the inner surface of a quartz glass crucible is in contact with a silicon melt, and is gradually eroded by reacting with the silicon melt. Here, in a case where there are many bubbles contained in the vicinity of the inner surface of the crucible, when the inner surface of the crucible is eroded and the internal bubbles appear on the surface, the bubbles expand and burst easily under high temperatures during crystal pull-up, crucible pieces (silica pieces) are delaminated from the inner surface of the crucible at this time and are incorporated into the silicon melt, resulting in unstable pull-up, problems in the pull-up step due to the incorporation into the single crystal (dislocation in the silicon single crystal, retrying of the pull-up step such as melt-back, and the like), and a reduction in single crystallization ratio. Therefore, a transparent layer that does not substantially contain bubbles is provided on the inner surface side of the crucible, and the outer side of the transparent layer is formed of an opaque layer containing a large number of bubbles.

In recent years, with the increase in aperture of a silicon single crystal pulled up by the CZ method, the problem of incorporation of bubbles in the growing single crystal and generation of pinholes in the single crystal has become noticeable. A pinhole is a bubble contained in a silicon single crystal and is a type of cavity defect. The bubbles are generated by aggregation of gas such as argon (Ar) gas dissolved in the silicon melt, or silicon monoxide (SiO) gas produced by the reaction between the quartz glass crucible and the silicon melt, at flaws or the like formed on the inner surface of the quartz crucible as the origins. It is considered that bubbles released from the inner surface of the crucible float in the silicon melt to reach the interface between the single crystal and the melt and are incorporated into the single crystal. Pinholes can only be found by slicing a silicon single crystal, and wafers in which pinholes are found after the slicing step are discarded as defective products. As described above, pinholes in a silicon single crystal are one of the factors that lower the manufacturing yield of silicon wafers.

Regarding a technology for preventing the generation of pinholes in a silicon single crystal, Patent Document 1 describes a method of setting the area of crystalline silica obtained by crystallization of amorphous silica to 10% or less of the area of the inner surface of a crucible, setting the density of recesses caused by open bubbles of the inner surface of the crucible to 0.01 to 0.2 pieces/mm², and suppressing the erosion rate of the inner surface of the crucible to 20 μm/hr or less, thereby preventing the generation of pinholes in the silicon single crystal.

Further, regarding a quartz crucible, Patent Document 2 describes a quartz glass crucible capable of preventing molten metal surface vibration. In this quartz glass crucible, molten metal surface vibration is suppressed by setting the bubble content of an upper portion higher than an initial molten metal surface descent position to 0.1% or more, an increase rate 0.002% to 0.008%, and the bubble content at a lower portion to be less than 0.1%.

Patent Document 3 describes that a quartz crucible for pulling up a silicon single crystal in which a transparent glass layer having a thickness of 1 mm or more is provided on the inner surface, the bubble content of the transparent glass layer in an inner circumferential surface part is 0.5% or less, and the bubble content of the transparent glass layer in a bottom surface part is 0.01% or less. In a manufacturing process of this quartz crucible, it is not necessary to reduce the bubble content for the entire crucible, and it is sufficient to heat the central part of the bottom portion of the crucible intensively and perform vacuum degassing, so that the manufacturing apparatus and control thereof are simple. Furthermore, it is also advantageous in terms of manufacturing cost.

Patent Document 4 describes a method of manufacturing a quartz glass crucible in which the inner layer of the crucible is formed of synthetic quartz powder, in which the inner part of the inner layer is formed of a first synthetic quartz powder, the surface side part of the inner layer is formed of a second synthetic quartz powder having an average particle size of 10 μm or more smaller than that of the first synthetic quartz powder, and thus the inner layer can be formed homogeneously even in a large-size crucible, whereby a quartz glass crucible having a low bubble content in the inner layer can be manufactured.

### BACKGROUND ART DOCUMENTS

### Patent Documents

Patent Document 1: Japanese Patent Application Laid-Open No. 2008-162865
Patent Document 2: Japanese Patent Application Laid-Open No. 2009-102206
Patent Document 3: Japanese Patent Application Laid-Open No. H6-191986
Patent Document 4: Pamphlet of International Publication No. WO2009/122936

### SUMMARY OF THE INVENTION

### Problems to be Solved by the Invention

However, in the quartz glass crucible in the related art described in Patent Document 1, the bubble content of the inner transparent layer is not specified, and in particular, the bubble content is not specified for each part of the crucible so that the generation of pinholes is effectively suppressed. Although it is described in Patent Document 1 that it is preferable that the recesses are present in the bottom portion of the crucible in a predetermined density, it is difficult to achieve both prevention of the generation of pinholes and improvement of the manufacturing yield of single crystals in this configuration. In addition, there is a limitation in use conditions such as pulling up of a silicon single crystal while suppressing the erosion rate of the inner surface of the crucible to 20 μm/hr or less.

Furthermore, although it is described in Patent Documents 2 to 4 that the delamination of silica pieces due to the bursting of the bubbles is prevented by lowering the bubble content of the transparent layer and thus the manufacturing yield of single crystals is increased, there is no description regarding means for effectively suppressing the generation of pinholes in single crystals.

Therefore, an object of the present invention is to provide a quartz glass crucible capable of achieving both improvement of the manufacturing yield of silicon single crystals and suppression of the generation of pinholes in single crystals.

### Means for Solving the Problems

The inventors of the present invention have intensively studied the relationship between the cause of pinholes in a single crystal and a quartz glass crucible, and as a result, found that it is not preferable to make the bubble content of the inner transparent layer of a quartz glass crucible as close to 0% as possible in order to suppress the generation of pinholes in a single crystal, and it is necessary to set an appropriate bubble content for each part of the crucible, so that the balance of the bubble contents is important. Heretofore, it has been considered that the bubble content of the inner transparent layer is desirably as low as possible from the viewpoint of preventing dislocation in the single crystal. However, it has become clear that in a case where a silicon single crystal is pulled up using a quartz glass crucible having an extremely low bubble content in the inner transparent layer, pinholes are more likely to be generated in a single crystal, and conversely, pinholes are less likely to be generated in a single crystal from a quartz crucible crucible containing a small amount of microbubbles in the inner transparent layer.

The present invention is based on such technical knowledge, and a quartz glass crucible according to the present invention includes: a straight body portion having a cylindrical shape; a bottom portion which is curved; and a corner portion provided between the straight body portion and the bottom portion, in which a bubble content of an inner surface layer portion ranging from an inner surface to a depth 0.5 mm in an upper portion of the straight body portion is 0.2% or more and 2% or less, the bubble content of the inner surface layer portion in a lower portion of the straight body portion is more than 0.1% and not more than 1.3 times a lower limit of the bubble content of the upper portion of the straight body portion, the bubble content of the inner surface layer portion in the corner portion is more than 0.1% and 0.5% or less, and the bubble content of the inner surface layer portion in the bottom portion is 0.1% or less.

According to the present invention, the bubble content of the inner surface layer portion ranging from the inner surface of the crucible to a depth of 0.5 mm is not too high nor too low, and is set in an appropriate range for each part of the crucible. Therefore, in pulling up a silicon single crystal by the CZ method, it is possible to grow a single crystal which does not contain pinholes, without lowering the manufacturing yield due to dislocations.

The range of the bubble content of each part of the crucible defined in the present invention means the range of the maximum value of the bubble content in the part. Therefore, for example, even if there is a region where the bubble content is 0.1% or less in a portion of the corner portion of the crucible, when the maximum value of the bubble content in the corner portion is more than 0.1% and not more than 0.5%, it can be said that the bubble content in the corner portion satisfies the conditions of the present invention. In this case, when the region satisfying the bubble content in each part of the crucible (for example, a region where the maximum value of the bubble content of the corner portion is more than 0.1% and not more than 0.5%) is present over a range of 20 mm or more, the dislocation suppression effect and the pinhole suppression effect according to the present invention can be stably exhibited.

In the present invention, it is preferable that an average diameter of bubbles contained in the inner surface layer portion is 50 μm or more and 500 μm or less. When the average diameter of the bubbles is in this range, it is possible to effectively suppress the generation of pinholes in single crystals while preventing dislocations in the single crystals caused by bursting of the bubbles.

### Advantages of the Invention

According to the present invention, it is possible to provide a quartz glass crucible capable of effectively suppressing the generation of pinholes in a single crystal without lowering the manufacturing yield of silicon single crystals. Therefore, according to the method of manufacturing a silicon single crystal by the CZ method using such a quartz glass crucible, it becomes possible to manufacture a high-quality single crystal not containing a pinhole, with a high yield.

### BRIEF DESCRIPTION OF DRAWINGS

FIG. 1 is a schematic side cross-sectional view illustrating the structure of a quartz glass crucible according to an embodiment of the present invention.

FIG. 2 is a schematic side cross-sectional view illustrating the usage state of the quartz glass crucible in a crystal pull-up step.

FIG. 3 is a graph showing the distribution of the bubble content of each sample, which is the result of an evaluation test of a 32-inch crucible.

FIG. 4 is a cross-sectional view of an inner surface layer portion of each part of the quartz glass crucible.

FIG. 5 is a graph showing the distribution of the bubble content of each sample, which is the result of an evaluation test of a 24-inch crucible.

FIG. 6 is a graph showing the result of evaluation of the correlation between the distribution of bubble contents and the bubble size of a 32-inch crucible.

### DETAILED DESCRIPTION OF THE EMBODIMENTS

Hereinafter, preferred embodiments of the present invention will be described in detail with reference to the accompanying drawings.

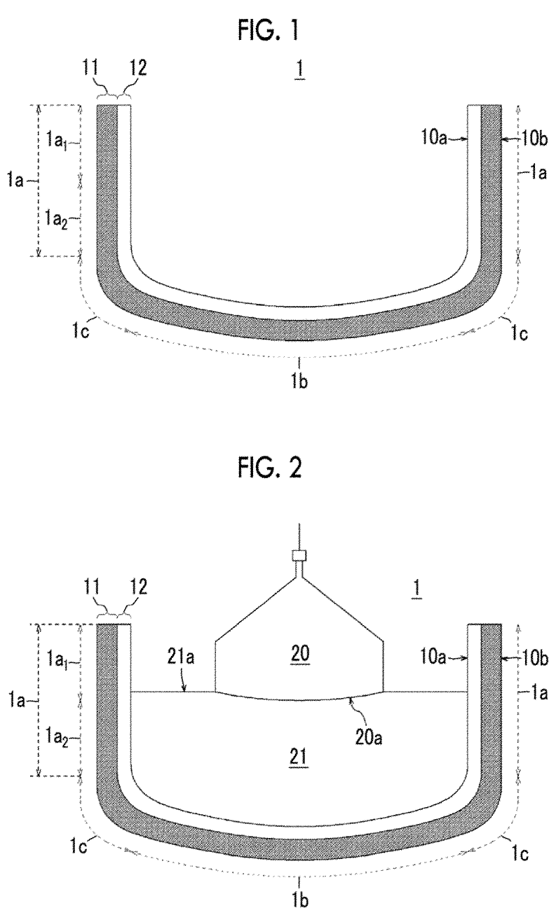

FIG. 1 is a schematic side cross-sectional view illustrating the structure of a quartz glass crucible according to an embodiment of the present invention.

As illustrated in FIG. 1, a quartz glass crucible 1 is a cylindrical container having a bottom for supporting a silicon melt, and includes a straight body portion 1a having a cylindrical shape, a bottom portion 1b which is gently curved, and a corner portion 1c which has a larger curvature than the bottom portion 1b and is provided between the straight body portion 1a and the bottom portion 1b.

The diameter (aperture) of the quartz glass crucible 1 is preferably 24 inches (about 600 mm) or more and is more preferably 32 inches (about 800 mm) or more. This is because such a crucible having a large aperture is used for pulling up a large-size silicon single crystal ingot having a diameter of 300 mm or more, and the probability that pinholes may be generated in a single crystal in the manufacturing of a large silicon single crystal ingot is high, so the effect of the present invention is remarkable.

Although the thickness of the crucible slightly varies depending on its part, the thickness of the straight body portion 1a of a crucible of 24 inches or more is preferably 8 mm or more, the thickness of the straight body portion 1a of a large crucible of 32 inches or more is preferably 10 mm or more, and the thickness of the straight body portion 1a of a large crucible of 40 inches (about 1000 mm) or more is preferably 13 mm or more.

The quartz glass crucible 1 has a two-layer structure, and includes an opaque layer 11 made of quartz glass containing a large number of bubbles, and a transparent layer 12 made of quartz glass with a very low bubble content.

The opaque layer 11 is a quartz glass layer that forms an outer surface 10b of the crucible wall and has an increased bubble content, and serves to cause radiant heat from a heater to be dispersed and uniformly transmitted to the silicon melt in the crucible. Therefore, it is preferable that the opaque layer 11 is provided in the entire crucible ranging from the straight body portion 1a to the bottom portion 1b of the crucible. The thickness of the opaque layer 11 is a value obtained by subtracting the thickness of the transparent layer 12 from the thickness of the crucible wall, and varies depending on the part of the crucible.

The bubble content of the quartz glass forming the opaque layer 11 is 0.8% or more, and preferably 1% to 5%. The bubble content of the opaque layer 11 can be obtained by specific gravity measurement (Archimedes' method). That is, the bubble content of the opaque layer 11 can be obtained by calculation from the mass of an opaque quartz glass piece of unit volume (1 cm³) cut out from a crucible and the specific gravity of the quartz glass with no bubbles contained therein (true density of quartz glass: 2.2 g/cm³).

The transparent layer 12 is a quartz glass layer in which the bubble content in the inner surface 10a of the crucible wall in contact with the silicon melt is reduced, and is provided to prevent crucible fragments delaminated from the inner surface 10a due to bursting of bubbles contained in the quartz glass from being incorporated into a solid/liquid interface and causing dislocation in a single crystal. The transparent layer 12 which is eroded by reacting with the silicon melt is required to be highly pure in order to prevent contamination of the silicon melt. The thickness of the transparent layer 12 is preferably 0.5 to 10 mm, and is set to an appropriate thickness for each part of the crucible so as not to expose the opaque layer 11 by being completely removed by erosion during a single crystal pull-up step. Similar to the opaque layer 11, it is preferable that the transparent layer 12 is provided over the entire crucible from the straight body portion 1a to the bottom portion 1b of the crucible.

However, in the upper end portion (rim portion) of the crucible which is not in contact with the silicon melt, it is also possible to omit formation of the transparent layer 12.

The bubble content of the transparent layer 12 is very low compared to the opaque layer 11, and the bubble content thereof is 2% or less although varying depending on the part of the crucible. The average size (diameter) of the bubbles is 500 μm or less. That is, the transparent layer 12 has a bubble content such that the single crystal does not have dislocations due to crucible fragments when the bubbles burst. Microbubbles contained in the transparent layer 12 are generated by the reaction between the silicon melt and the crucible, and play a role of promoting the vaporization of SiO dissolved in the silicon melt. A change in the bubble content at the boundary between the opaque layer 11 and the transparent layer 12 is steep, and the boundary between the two is apparent with the naked eye.

The number and size of bubbles present in a predetermined range in the depth direction from the inner surface 10a of the crucible can be measured nondestructively using optical detecting means. The optical detecting means includes a light-receiving device which receives the reflected light of the light irradiating the inner surface 10a of a crucible to be inspected. Irradiation light-emitting means may be built in or external light-emitting means may also be used. In addition, as the optical detecting means, one that can be turned along the inner surface 10a of the crucible is preferable. As the irradiation light, X-rays, laser light, and the like as well as visible light, ultraviolet light, and infrared light can be used, and any light can be applied as long as the light can be reflected for bubble detection. The light-receiving device is selected according to the type of the irradiation light, and for example, an optical camera including a light-receiving lens and an imaging unit can be used.

Measurement results obtained by the optical detecting means are received by an image processing device to calculate the bubble content. Specifically, when an image of the inner surface of the crucible is taken using the optical camera, the focal point of a light-receiving lens is scanned in a depth direction from the surface to photograph a plurality of images, the volumes of bubbles are obtained from the sizes of the bubbles photographed in each of the images, and the bubble content, which is the volume of the bubbles per unit volume, can be obtained from the sum of the volumes of the bubbles of each of the images.

It is preferable to measure the bubble content in the vicinity of the inner surface of a crucible using an automatic measuring machine. In the automatic measuring machine, an optical camera provided at the tip of the arm robot photographs the inner surface at a constant pitch while moving along the inner surface 10a of the crucible, and measures the bubble content at each measurement point. According to the measurement of the bubble content using the automatic measuring machine, it is possible to accurately measure the bubble content in the vicinity of the inner surface of the crucible within a short period of time.

The feature of the quartz glass crucible 1 according to the present embodiment is that the bubble content in the vicinity of the inner surface in the straight body portion 1a and the corner portion 1c is not too low, and has an appropriate bubble content. As described above, in a case where the bubble content in the vicinity of the inner surface of the crucible is high, the bubbles in the quartz glass appear on the surface when the inner surface 10a is eroded by contact with the silicon melt, and burst due to thermal expansion, and this increases the probability that crucible pieces (silica pieces) may delaminate from the inner surface 10a. The silica pieces are moved to the solid/liquid interface by the convection of the melt and are incorporated into the single crystal, such that dislocation occurs in the single crystal during pull-up. Therefore, it has been considered desirable to reduce the bubble content in the vicinity the inner surface of the crucible as much as possible.

However, in a case where the bubble content in the vicinity of the inner surface of the crucible is lower than that of the entire inner surface of the crucible, there is no origin where SiO generated by the reaction between the silicon melt and the crucible and dissolved in the melt is aggregated and gasified. Therefore, after the SiO concentration in the melt increases to near the critical value of supersaturation, SiO is gasified at once and forms a large bubble in the melt. Such a large bubble does not dissolve into the silicon melt again, and when the bubble generation position is below the single crystal, the bubble ascending in the melt is incorporated into the single crystal and becomes a pinhole. That is, when the bubble content is too low, the silicon melt is vulnerable to explosive boiling, and the probability that the bubbles generated by the explosive boiling may be incorporated into the single crystal being pulled up becomes high.

Therefore, in the present embodiment, by setting an appropriate bubble content depending on the part of the crucible, while preventing the delamination of crucible fragments due to the bursting of the bubbles, the generation of pinholes due to the incorporation of the bubbles in the melt into the single crystal is prevented.

In an inner surface layer portion ranging from the inner surface 10a of the crucible to a depth of 0.5 mm, the bubble content of the inner surface layer portion of the straight body portion 1a is preferably 0.1 to 2%. In a case where the bubble content of the inner surface layer portion of the straight body portion 1a exceeds 2%, dislocations easily occur in the silicon single crystal, and the manufacturing yield of the silicon single crystal is reduced. In a case where the bubble content of the inner surface layer portion of the straight body portion 1a is 0.1% or less, the effect of vaporizing gas components such as SiO dissolved in the silicon melt is not sufficient, and the effect of suppressing the generation of pinholes in a single crystal by including bubbles in the inner surface layer portion is not obtained. However, by increasing the bubble content of the inner surface layer portion of the straight body portion 1a to such an extent that delamination of crucible pieces due to bursting of the bubbles does not occur, the gas components dissolved in the silicon melt, which may cause pinholes, are positively discharged, and thus the SiO concentration in the melt can be reduced.

FIG. 2 is a schematic side cross-sectional view illustrating the usage state of the quartz glass crucible 1 in a crystal pull-up step.

As illustrated in FIG. 2, the amount of the silicon melt 21 in the crucible is increased due to the increase in the aperture of the silicon single crystal 20 and the quartz glass crucible 1, and in order to cause the temperature of a solid/liquid interface 20a to be constant, the temperature of the straight body portion 1a of the crucible needs to be set to a temperature as high as 1600° C. or higher. On the other hand, at the bottom portion 1b of the crucible (the lower portion of the silicon melt 21), the pressure of the silicon melt 21 is high, and the temperature of the melt itself is also low. Therefore, SiO generated by the reaction between the silicon melt 21 and the crucible and dissolved in the silicon melt 21 is in a state of being less likely to gasify. Contrary to this, since the pressure of the melt itself is low at the upper portion of the silicon melt 21 (near a melt surface 21a) and the temperature of the melt is also high as described above, SiO dissolved in the silicon melt 21 is more likely to gasify.

Pinholes are generated when bubbles generated at the bottom portion 1b of the crucible ascend and adhere to the solid/liquid interface 20a. Therefore, in a case where bubbles are generated below the silicon single crystal 20, the bubbles are more likely to be incorporated into the single crystal. On the other hand, bubbles generated at the inner surface 10a of the straight body portion 1a ascend almost straight in the melt with some fluctuation, and since the straight body portion 1a is at a position of 100 mm or more away from the silicon single crystal 20, the possibility that the bubbles generated at the straight body portion 1a may be incorporated into the silicon single crystal 20 is extremely low.

Therefore, in the present embodiment, by causing the bubble content of the inner surface layer portion of the straight body portion 1a of the crucible in contact with the upper portion of the silicon melt to be relatively high, gasification of SiO is promoted. When bubbles in the quartz glass are exposed on the inner surface 10a of the crucible, minute SiO bubbles are generated in the melt from the bubbles as the origins. The bubbles of SiO generated at the straight body portion 1a ascend in the melt without being dissolved again in the silicon melt. However, since the bubbles of SiO generated at the bottom portion 1b of the crucible are very small, the bubbles are not dissolved in the melt again and incorporated into the single crystal. Therefore, the generation of pinholes due to the bubbles being incorporated into the single crystal can be suppressed.

It is preferable that the bubble content of the upper side of the straight body portion 1a of the crucible is higher than the bubble content of the lower side of the straight body portion 1a of the crucible. More specifically, it is preferable that the bubble content of the inner surface layer portion of an upper portion 1a₁ of the straight body portion 1a which is a part above the middle point in the vertical direction in the straight body portion 1a of the crucible is 0.2 to 2%. In addition, the bubble content of the inner surface layer portion of a lower portion 1a₂ of the straight body portion 1a is more than 0.1%, preferably 1.3 times or less the lower limit of the bubble content of the inner surface layer portion of the upper portion 1a₁ of the straight body portion 1a, and particularly preferably 1.2 times or less.

As the crystal pull-up step proceeds, the silicon melt is consumed, the amount of the melt decreases, and the position of the melt surface also lowers. Therefore, the upper portion 1a₁ of the straight body portion 1a has a shorter contact time with the silicon melt than the lower portion 1a₂, and the amount of erosion of the inner surface 10a of the crucible is also small. Conversely, the lower portion 1a₂ of the straight body portion 1a has a longer contact time with the silicon melt than the upper portion 1a₁, and the amount of erosion of the inner surface 10a is also large. Therefore, the probability of generating dislocations and pinholes increases as the position of the melt surface lowers in the crucible. The stage in which the upper portion 1a₁ of the straight body portion 1a is in contact with the silicon melt is also an initial stage of the crystal pull-up step, and either during a step of growing the shoulder of a silicon single crystal or immediately after the start of a step of growing a body portion with a constant diameter, so the effects of dislocations and pinholes are small.

Furthermore, since the upper portion 1a₁ of the straight body portion 1a corresponds to the initial molten metal surface position, the effect of suppressing molten metal surface vibration can also be expected by increasing the bubble content. For this reason, in the present embodiment, the bubble content of the upper portion 1a₁ of the straight body portion 1a which is contact with the silicon melt for a short period of time is relatively increased, and the bubble content of the lower portion 1a₂ of the straight body portion 1a which is contact with the silicon melt for a long period of time is relatively decreased.

The upper limit and the lower limit of the bubble content of the upper portion 1a₁ of the straight body portion 1a are present respectively near the upper end and the lower end of the upper portion 1a₁ of the straight body portion, and the bubble content of the straight body portion 1a preferably gradually decreases downward from the upper end portion. In particular, it is preferable that the upper limit of the bubble content of the upper portion 1a₁ of the straight body portion 1a is 1.5 times or more of the lower limit. For example, the bubble content in the vicinity of the upper end of the straight body portion 1a is 1.0% and gradually decreases downward, and the bubble content in the vicinity of the lower end of the straight body portion 1a may become 0.1%. Accordingly, the optimal bubble content according to the height position of the straight body portion 1a can be set.

The bubble content of the inner surface layer portion of the corner portion 1c is preferably 0.1 to 0.5%. In a case where the bubble content in the inner surface layer portion of the corner portion 1c exceeds 0.5%, dislocations easily occur in the silicon single crystal, and the manufacturing yield of the silicon single crystal is reduced. In addition, in a case where the bubble content of the inner surface layer portion of the corner portion 1c is 0.1% or less, the effect of vaporizing gas components such as SiO dissolved in the silicon melt is not sufficient, and the effect of suppressing the generation of pinholes in a single crystal by including bubbles in the inner surface layer portion is not obtained.

In a case where a part with a relatively high bubble content is provided only in the vicinity of the inner surface of the upper portion of the straight body portion of the crucible, although the effect of suppressing the generation of large bubbles can be obtained while the part is in contact with the melt, after the part is not in contact with the melt, the same situation as described above is incurred.

However, by increasing the bubble content of the corner portion 1c to such an extent that delamination of crucible pieces due to bursting of the bubbles does not occur, the effect of discharging SiO dissolved in the silicon melt which may cause pinholes, is enhanced and thus the SiO concentration in the melt can be reduced. The corner portion 1c is a part that is in contact with the silicon melt until the final stage of the pull-up step and is closer to the center of the crucible than the straight body portion 1a, so that the effect thereof in a case where delamination of crucible piece occurs or large bubbles are generated at the corner portion 1c is larger than that at the straight body portion 1a. However, since the bubble content is set to be lower than that of the straight body portion 1a so that delamination of crucible pieces due to bursting of bubbles or the generation of large bubbles which cause pinholes is less likely to occur, such problems can be avoided.

Unlike the straight body portion 1a and the corner portion 1c, the bubble content of the inner surface layer portion of the bottom portion 1b is preferably as low as possible, and particularly preferably less than 0.05%. When the bubble content in the inner surface layer portion of the bottom portion 1b is increased, bubbles are more likely to be generated in the bottom portion 1b, and the probability that the bubbles may be incorporated into the single crystal is increased. In addition, when appropriate bubble contents for the straight body portion 1a and the corner portion 1c are set, a sufficient pinhole suppression effect is obtained even if the bubble content of the bottom portion 1b is not increased.

The bottom portion 1b of the crucible is in contact with the silicon melt from the start to the end of crystal pull-up and has a longer contact time with the silicon melt than the straight body portion 1a or the corner portion 1c, and the amount of erosion of the inner surface of the crucible is also large. Therefore, when the bubble content is not lowered sufficiently, the amount of bubbles appearing on the surface increases, the probability that silica pieces may be delaminated due to bursting of bubbles, or pinholes may be generated in the single crystal due to large bubbles generated from bubbles used as the starting points increases. Therefore, it is necessary to cause the bubble content at the bottom portion 1b of the crucible to be extremely low. Since the bubbles of SiO generated at the bottom portion 1b of the crucible are small, the bubbles are not dissolved again in the melt and incorporated into the single crystal.

In the straight body portion 1a, very small bubbles included so that silica pieces are not delaminated by bursting, and by causing SiO in the melt to be aggregated from the small bubbles as the origins and be gasified to be positively discharged to the outside of the melt, the concentration of SiO dissolved in the melt can be reduced. In this case, even if SiO in the melt is aggregated from bubble-generating nuclei such as microbubbles as the origins at the bottom portion of the crucible and bubbles are generated, the bubbles are very small and can dissolve again in the melt. Therefore, it is possible to prevent large bubbles generated at the bottom portion of the crucible by explosive boiling from being incorporated into the single crystal.

The range of the bubble content of each part of the crucible defined in the present invention means the range of the maximum value of the bubble content in the part. Therefore, even if there is a region not satisfying the bubble content condition in a portion of each part of the crucible, when the maximum value of the bubble content of another portion satisfies the condition, it can be said that the entire corner portion satisfies the conditions of the bubble content of the present invention. In this case, when the region satisfying the bubble content in each part is present over a range of 20 mm or more, the dislocation suppression effect and the pinhole suppression effect according to the present invention can be stably exhibited.

Although the bubble content of the inner surface layer portion of the crucible slightly fluctuates vertically, it is preferable that the bubble content thereof substantially gradually increases from the lower end of the corner portion 1c toward the upper end of the straight body portion 1a. Therefore, it is preferable that the lower limit of the bubble content of the corner portion 1c is located closer to the lower end of the corner portion 1c, and the upper limit of the bubble content of the corner portion 1c is located closer to the upper end of the corner portion 1c. Furthermore, it is preferable that the lower limit of the bubble content of the straight body portion 1a is located closer to the lower end of the straight body portion 1a, and the upper limit of the bubble content of the straight body portion 1a is located closer to the upper end of the straight body portion 1a.

The average diameter of the bubbles contained in the inner surface layer portion of the crucible is preferably 50 to 500 μm. In a case where large bubbles exceeding 500 jam are contained, there is a high possibility that crucible pieces may be delaminated due to bursting of the bubbles, which may affect the pull-up yield. In addition, it is considered that evaluation of very fine bubbles having a diameter of less than 50 μm is difficult, and there is almost no effect of suppressing the generation of pinholes. That is, explosive boiling tends to occur on the inner surface of the crucible, and large bubbles rise in the silicon melt and are incorporated into the ingot to generate pinholes. The inner surface layer portion of the crucible may contain bubbles having a diameter of 50 μm or less, but it is preferable that bubbles having a diameter of 500 μm or more are not present.

There is a correlation between the bubble content and the bubble size. As the bubble content increases, the number of bubbles having large sizes increases, and as the bubble content decreases, the number of bubbles having large sizes decreases and the number of bubbles having small sizes increases. It is difficult to include only bubbles having very small sizes. Therefore, by setting the bubble content for each portion of the crucible to be in an appropriate range which is not too high or too low, it is possible to optimize the bubble content and the average bubble size for each part of the crucible.

The surface roughness (arithmetic average roughness Ra) of the inner surface 10a of the crucible is preferably 0.001 μm to 0.2 μm. This is because, in a case where the surface roughness is higher than 0.2 μm, the inner surface is delaminated and dislocations easily occur in the single crystal, and it is difficult to cause the surface roughness to be 0.001 μm or less in terms of production. However, in a case where the arithmetic average roughness Ra of the inner surface 10a of the crucible is 0.001 μm to 0.2 μm, it is possible to suppress dislocations in the single crystal due to delamination of the inner surface of the crucible.

The quartz glass crucible 1 according to the present embodiment can be manufactured by a so-called rotational molding method. In the rotational molding method, using a carbon mold having an inner surface shape matched to the external shape of the crucible, quartz powder is introduced into the rotating mold, and the quartz powder is deposited on the inner surface of the mold with a constant thickness. At this time, the amount of the quartz powder deposited is adjusted so that the thickness of the crucible becomes as designed for each part. Since the quartz powder adheres to the inner surface of the crucible by centrifugal force and maintains the shape of the crucible, by subjecting the quartz powder to arc melting, a silica glass crucible is manufactured.

At the time of the arc melting, by reducing the pressure from the mold side, gas in the melted quartz is suctioned to the outside through a ventilation hole provided in the mold and is discharged to the outside through the ventilation hole, whereby the transparent layer 12 from which bubbles are eliminated is formed in the vicinity of the inner surface of the crucible. At this time, the suction time (vacuum drawing time) for a part where the transparent layer 12 is desired to be thin (the opaque layer 11 is desired to be thick) may be shortened, and the suction time for a part where the transparent layer 12 is desired to be thick (the opaque layer 11 is desired to be thin) may be lengthened. Thereafter, the suction force of all the ventilation holes is reduced (or stopped), and furthermore, heating is continued to leave bubbles, whereby the opaque layer 11 containing a large number of microbubbles is formed on the outside of the transparent layer 12.

In the rotational molding method, by changing conditions such as the type (particle diameter) of the quartz raw material powder, the arc output level, the heating time, and the pressure and time for vacuum drawing of the mold for each part of the crucible, an appropriate bubble content and a bubble size for each part of the crucible can be set. For example, when the particle size of the raw material quartz powder is small, small bubbles are likely to be generated and the bubble content decreases. However, when the particle size is large, large bubbles are likely to be generated and the bubble content increases. In addition, the higher the carbon content in the raw material quartz powder, the higher the bubble content tends to be. In addition, when the power output of arc heating is large, the number of bubbles is small, and when the power output is small, the number of bubbles is large. The longer the heating time, the lower the bubble content. Conversely, the shorter the heating time, the higher the bubble content. Furthermore, the stronger the suction power, the lower the bubble content, and the weaker the suction power, the higher the bubble content.

As described above, in the quartz glass crucible 1 according to the present embodiment, the bubble content of the inner surface layer portion ranging from the inner surface to a depth of 0.5 mm is set in an appropriate range for each part of the crucible, and the average diameter of bubbles is 50 to 500 μm. Therefore, dislocations being caused by the bubble content being too high and also generation of pinholes in the single crystal due to the bubble content being too low can be effectively suppressed. In particular, in the present embodiment, since the bubble content of the upper portion 1a₁ of the straight body portion 1a of the crucible is higher than the bubble content of the lower portion 1a₂ of the straight body portion 1a, a gas component such as SiO dissolved in silicon melt can be positively discharged, whereby generation of pinholes in a single crystal can be effectively suppressed. Furthermore, as in the upper portion 1a₁ of the straight body portion 1a, although the bubble content of the lower portion 1a₂ of the straight body portion 1a and the corner portion 1c is higher than that of the bottom portion 1b, in consideration of the fact that the lower portion 1a₂ of the straight body portion 1a has a longer contact time with the silicon melt than the upper portion 1a₁, and the corner portion 1c has an even longer contact time with the silicon melt than the lower portion 1a₂ of the straight body portion 1a, the bubble content is lowered toward the lower part of the crucible, so that dislocations in the single crystal can be reliably prevented while suppressing generation of pinholes in the single crystal.

While the preferred embodiments of the present invention have been explained above, the present invention is not limited to the embodiments and may be variously modified without departing from the scope of the present invention. Accordingly, all such modifications are included in the present invention.

### EXAMPLES

(Example 1: Evaluation Test of 32-inch Crucible) Sample S1 of a quartz glass crucible having a diameter of 32 inches was prepared, and the distribution of the bubble content in the vicinity of the inner surface was measured. In the measurement of the bubble content, an automatic measuring machine was used, and the bubble content was calculated by specifying the sizes of bubbles present in a range from the inner surface to a depth of about 0.5 mm in a 5×5 mm region at each measurement point.

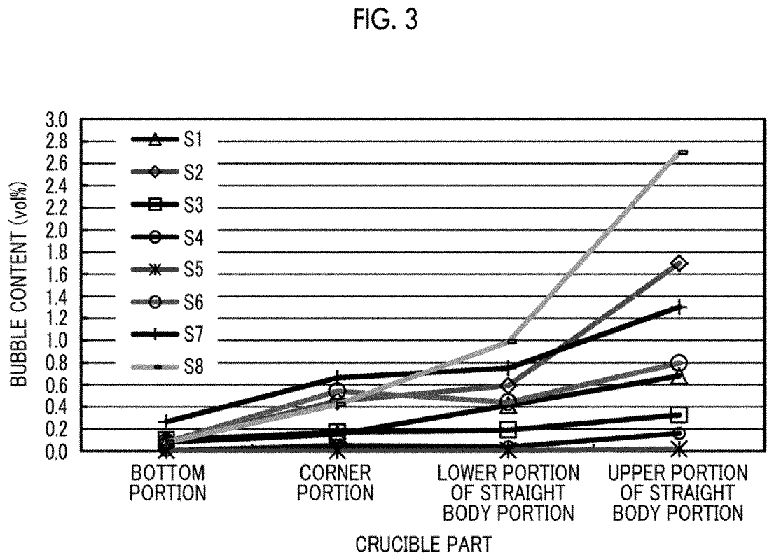

In the measurement of the bubble content, the measurement was performed at a pitch of 20 mm in the radial direction (vertical direction) from the center of the bottom portion of the crucible toward the upper end of the rim. As a result, the bubble content of crucible sample S1 was 0 to 0.10% at the bottom portion, 0.12 to 0.15% at the corner portion, 0.13 to 0.41% at the lower portion of the straight body portion, and 0.45 to 0.68% at the upper portion of the straight body portion. The range of each part of the crucible with respect to the center of the bottom portion of the 32-inch crucible was 0 to 300 mm at the bottom portion, 300 to 500 mm at the corner portion, 500 to 650 mm at the lower portion of the straight body portion, and 650 to 800 mm at the upper portion of the straight body portion. The maximum value of the bubble content in each part of crucible sample S1 is shown in the graph of FIG. 3.

Next, using five quartz glass crucibles of the same type manufactured under the same conditions including sample S1 of the quartz glass crucible, silicon single crystals were pulled up five times by the CZ method, and the pull-up yield was evaluated. The pull-up yield of the single crystal was evaluated as “good” when no dislocation had occurred even once in the five pull-up operations, and “poor” when dislocation had occurred even once. As a result of the evaluation, as shown in Table 1, dislocation-free silicon single crystal ingots could be pulled up five times without any problems, and the pull-up yield was good.

TABLE 1

| Crucible sample | Pull-up yield | Pinhole |
|---|---|---|
| S1 | Good | Good |
| S2 | Good | Good |
| S3 | Good | Good |
| S4 | Good | Poor |
| S5 | Good | Poor |
| S6 | Poor | Good |
| S7 | Poor | Good |
| S8 | Poor | Good |

Next, the presence or absence of pinholes in the five obtained silicon single crystal ingots was evaluated. The evaluation of the presence or absence of pinholes was performed by inspecting the presence or absence of pinholes in a silicon wafer obtained by processing the silicon single crystal ingot with an infrared inspection device. As a result, as shown in Table 1, no pinhole defect was detected in any single crystal ingot.

Sample S2 of a quartz glass crucible manufactured under different conditions from those of sample S1 was prepared, and the distribution of the bubble content in the vicinity of the inner surface was measured. The bubble content of crucible sample S2 was 0 to 0.10% at the bottom portion, 0.12 to 0.45% at the corner portion, 0.47 to 0.59% at the lower portion of the straight body portion, and 0.53 to 1.7% at the upper portion of the straight body portion. The maximum value of the bubble content in each part of crucible sample S2 is shown in the graph of FIG. 3.

Next, using five quartz glass crucibles of the same type manufactured under the same conditions including sample S2 of the quartz glass crucible, silicon single crystals were pulled up five times by the CZ method. As a result, as shown in Table 1, dislocation-free silicon single crystal ingots could be pulled up five times without any problems, and the pull-up yield was good. Moreover, when the presence or absence of pinholes in the five obtained silicon single crystal ingots was evaluated, as shown in Table 1, no pinhole defect was detected.

Sample S3 of a quartz glass crucible manufactured under different conditions from those of samples S1 and S2 was prepared, and the distribution of the bubble content in the vicinity of the inner surface was measured. The bubble content of crucible sample S3 was 0 to 0.10% at the bottom portion, 0.12 to 0.17% at the corner portion, 0.15 to 0.19% at the lower portion of the straight body portion, and 0.19 to 0.33% at the upper portion of the straight body portion. The maximum value of the bubble content in each part of crucible sample S3 is shown in the graph of FIG. 3.

Next, using five quartz glass crucibles of the same type manufactured under the same conditions including sample S3 of the quartz glass crucible, silicon single crystals were pulled up five times by the CZ method. As a result, as shown in Table 1, dislocation-free silicon single crystal ingots could be pulled up five times without any problems, and the pull-up yield was good. Moreover, when the presence or absence of pinholes in the five obtained silicon single crystal ingots was evaluated, as shown in Table 1, no pinhole defect was detected.

Sample S4 of a quartz glass crucible manufactured under different conditions from those of samples S1 to S3 was prepared, and the distribution of the bubble content in the vicinity of the inner surface was measured. The bubble content of crucible sample S4 was 0 to 0.01% at the bottom portion, 0.01 to 0.04% at the corner portion, 0.02% to 0.04% at the lower portion of the straight body portion, and 0.04% to 0.16% at the upper portion of the straight body portion. The maximum value of the bubble content in each part of crucible sample S4 is shown in the graph of FIG. 3.

Next, using five quartz glass crucibles of the same type manufactured under the same conditions including sample S4 of the quartz glass crucible, silicon single crystals were pulled up five times by the CZ method. As a result, as shown in Table 1, dislocation-free silicon single crystal ingots could be pulled up five times without any problems, and the pull-up yield was good. However, when the presence or absence of pinholes in the five obtained silicon single crystal ingots was evaluated, pinhole defects were detected.

Sample S5 of a quartz glass crucible manufactured under different conditions from those of samples S1 to S4 was prepared, and the distribution of the bubble content in the vicinity of the inner surface was measured. The bubble content of crucible sample S5 was 0% at the bottom portion, 0% at the corner portion, 0 to 0.01% at the lower portion of the straight body portion, and 0.01 to 0.02% at the upper portion of the straight body portion. The maximum value of the bubble content in each part of crucible sample S5 is shown in the graph of FIG. 3.

Next, using five quartz glass crucibles of the same type manufactured under the same conditions including sample S5 of the quartz glass crucible, silicon single crystals were pulled up five times by the CZ method. As a result, as shown in Table 1, dislocation-free silicon single crystal ingots could be pulled up five times without any problems, and the pull-up yield was good. However, when the presence or absence of pinholes in the five obtained silicon single crystal ingots was evaluated, pinhole defects were detected.

Sample S6 of a quartz glass crucible manufactured under different conditions from those of samples S1 to S5 was prepared, and the distribution of the bubble content in the vicinity of the inner surface was measured. The bubble content of crucible sample S6 was 0 to 0.20% at the bottom portion, 0.21 to 0.54% at the corner portion, 0.24 to 0.44% at the lower portion of the straight body portion, and 0.47 to 0.80% at the upper portion of the straight body portion. The maximum value of the bubble content in each part of crucible sample S6 is shown in the graph of FIG. 3.

Next, using five quartz glass crucibles of the same type manufactured under the same conditions including sample S6 of the quartz glass crucible, silicon single crystals were pulled up five times by the CZ method. As a result, as shown in Table 1, dislocations had occurred, so that the pull-up yield was poor. When the presence or absence of pinholes in the five obtained silicon single crystal ingots was evaluated, no pinhole defect was detected. It is considered that in sample S6, the bubble content of a portion of the corner portion exceeded 0.5%, so that the pull-up yield was reduced due to the occurrence of dislocations.

Sample S7 of a quartz glass crucible manufactured under different conditions from those of samples S1 to S6 was prepared, and the distribution of the bubble content in the vicinity of the inner surface was measured. The bubble content of crucible sample S7 was 0 to 0.31% at the bottom portion, 0.33 to 0.66% at the corner portion, 0.66 to 0.75% at the lower portion of the straight body portion, and 0.73 to 1.3% at the upper portion of the straight body portion. The maximum value of the bubble content in each part of crucible sample S7 is shown in the graph of FIG. 3.

Next, using five quartz glass crucibles of the same type manufactured under the same conditions including sample S7 of the quartz glass crucible, silicon single crystals were pulled up five times by the CZ method. As a result, as shown in Table 1, dislocations had occurred, so that the pull-up yield was poor. When the presence or absence of pinholes in the five obtained silicon single crystal ingots was evaluated, no pinhole defect was detected. It is considered that in sample S7, the bubble content of a portion of the bottom portion exceeded 0.1%, and the bubble content of a portion of the corner portion exceeded 0.5%, so that the pull-up yield was reduced due to the occurrence of dislocations.

Sample S8 of a quartz glass crucible manufactured under different conditions from those of samples S1 to S7 was prepared, and the distribution of the bubble content in the vicinity of the inner surface was measured. The bubble content of crucible sample S8 was 0 to 0.10% at the bottom portion, 0.11 to 0.42% at the corner portion, 0.44 to 0.99% at the lower portion of the straight body portion, and 0.95 to 0.2.7% at the upper portion of the straight body portion. The maximum value of the bubble content in each part of crucible sample S8 is shown in the graph of FIG. 3.

Next, using five quartz glass crucibles of the same type manufactured under the same conditions including sample S8 of the quartz glass crucible, silicon single crystals were pulled up five times by the CZ method. As a result, as shown in Table 1, dislocations had occurred, so that the pull-up yield was poor. When the presence or absence of pinholes in the five obtained silicon single crystal ingots was evaluated, no pinhole defect was detected. It is considered that in sample S8, the bubble content of the upper portion of the straight body portion exceeded 2%, so that the pull-up yield was reduced due to the occurrence of dislocations.

From the above results, in samples S1 to S3 of the quartz glass crucibles in which the bubble content of the upper portion of the straight body portion was in a range of 0.2 to 2%, the bubble content of the lower portion of the straight body portion was in a range of 0.1 to 1%, and the bubble content of the corner portion was in a range of 0.1 to 0.5%, the pull-up yield was good, and no pinholes were generated, so that good results were obtained. However, in samples S4 and S5, the bubble content was too low, so that pinholes were generated in the single crystal. In addition, in samples S6 to S8, the bubble content was too high, so that dislocations had occurred, resulting in deterioration of the pull-up yield.

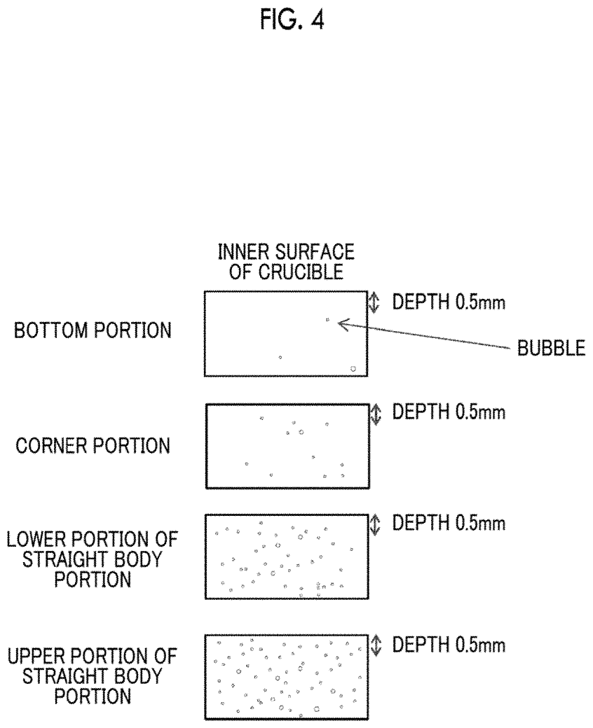

FIG. 4 is a cross-sectional view of the inner surface layer portion in the bottom portion, the corner portion, the lower portion of the straight body portion, and the upper portion of the straight body portion of sample S3 of the quartz glass crucible.

As illustrated in FIG. 4, although the presence of bubbles could hardly be confirmed at the bottom portion of the crucible, the presence of a small amount of microbubbles could be clearly confirmed at the corner portion, the amount of bubbles gradually increased toward the upper end of the crucible, and the presence of a large amount of bubbles could be confirmed at the upper portion of the straight body portion.

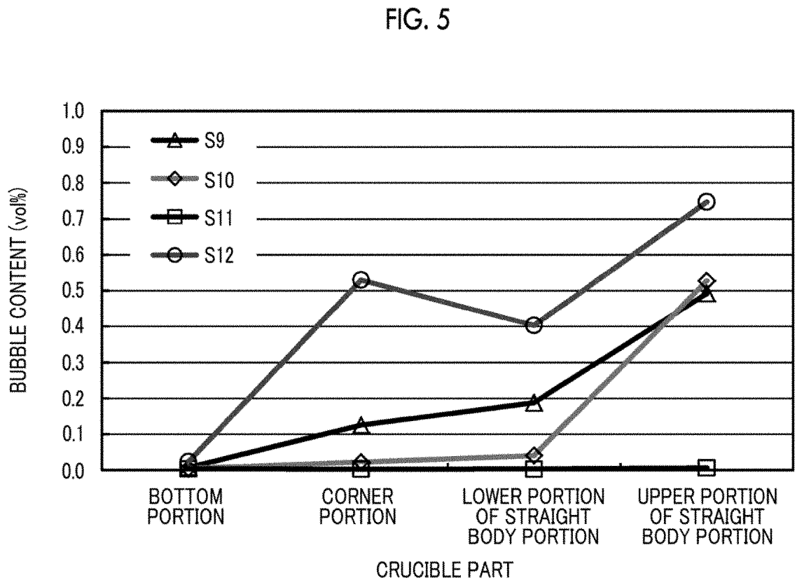

(Example 2: Evaluation Test of 24-inch Crucible) Sample S9 of a quartz glass crucible having a diameter of 24 inches was prepared, and the distribution of the bubble content in the vicinity of the inner surface was measured. The bubble content of crucible sample S9 was 0% at the bottom portion, 0 to 0.12% at the corner portion, 0.15 to 0.19% at the lower portion of the straight body portion, and 0.20 to 0.50% at the upper portion of the straight body portion. The range of each part of the crucible with respect to the center of the bottom portion of the 24-inch crucible was 0 to 240 mm at the bottom portion, 240 to 400 mm at the corner portion, 400 to 510 mm at the lower portion of the straight body portion, and 510 to 620 mm at the upper portion of the straight body portion. The maximum value of the bubble content in each part of crucible sample S9 is shown in the graph of FIG. 5.

Next, using five quartz glass crucibles of the same type manufactured under the same conditions including sample S9 of the quartz glass crucible, silicon single crystals were pulled up five times by the CZ method. As a result, as shown in Table 2, dislocation-free silicon single crystal ingots could be pulled up five times without any problems, and the pull-up yield was good. Moreover, when the presence or absence of pinholes in the five obtained silicon single crystal ingots was evaluated, no pinhole defect was detected in any single crystal ingot.

TABLE 2

| Crucible sample | Pull-up yield | Pinhole |
|---|---|---|
| S9 | Good | Good |
| S10 | Good | Poor |
| S1l | Good | Poor |
| S12 | Poor | Good |

Sample S10 of a quartz glass crucible manufactured under different conditions from those of sample S9 was prepared, and the distribution of the bubble content in the vicinity of the inner surface was measured. The bubble content of crucible sample S10 was 0% at the bottom portion, 0 to 0.02% at the corner portion, 0.02 to 0.04% at the lower portion of the straight body portion, and 0.11 to 0.53% at the upper portion of the straight body portion. The maximum value of the bubble content in each part of crucible sample S10 is shown in the graph of FIG. 5.

Next, using five quartz glass crucibles of the same type manufactured under the same conditions including sample S10 of the quartz glass crucible, silicon single crystals were pulled up five times by the CZ method. As a result, as shown in Table 2, dislocation-free silicon single crystal ingots could be pulled up five times without any problems, and the pull-up yield was good. However, when the presence or absence of pinholes in the five obtained silicon single crystal ingots was evaluated, pinhole defects were detected.

Sample S11 of a quartz glass crucible manufactured under different conditions from those of samples S9 and S10 was prepared, and the distribution of the bubble content in the vicinity of the inner surface was measured. The bubble content of crucible sample S11 was 0% in a range from the bottom portion to the upper portion of the straight body portion. The maximum value of the bubble content in each part of crucible sample S11 is shown in the graph of FIG. 5.

Next, using five quartz glass crucibles of the same type manufactured under the same conditions including sample S11 of the quartz glass crucible, silicon single crystals were pulled up five times by the CZ method. As a result, as shown in Table 2, dislocation-free silicon single crystal ingots could be pulled up five times without any problems, and the pull-up yield was good. However, when the presence or absence of pinholes in the five obtained silicon single crystal ingots was evaluated, pinhole defects were detected.

Sample S12 of a quartz glass crucible manufactured under different conditions from those of samples S9 to S11 was prepared, and the distribution of the bubble content in the vicinity of the inner surface was measured. The bubble content of crucible sample S12 was 0 to 0.02% at the bottom portion, 0.05 to 0.53% at the corner portion, 0.23 to 0.40% at the lower portion of the straight body portion, and 0.46 to 0.75% at the upper portion of the straight body portion. The maximum value of the bubble content in each part of crucible sample S12 is shown in the graph of FIG. 5.

Next, using five quartz glass crucibles of the same type manufactured under the same conditions including sample S12 of the quartz glass crucible, silicon single crystals were pulled up five times by the CZ method. As a result, as shown in Table 2, dislocations had occurred, so that the pull-up yield was poor. When the presence or absence of pinholes in the five obtained silicon single crystal ingots was evaluated, no pinhole defect was detected. It is considered that in sample S12, since the bubble content of the corner portion was a very high bubble content exceeding 0.5%, dislocations had occurred.

From the above results, in sample S9 of the quartz glass crucible in which the bubble content of the upper portion of the straight body portion was in a range of 0.2 to 2%, the bubble content of the lower portion of the straight body portion was in a range of 0.1 to 1%, and the bubble content of the corner portion was in a range of 0.1 to 0.5%, the pull-up yield was good, and no pinholes were generated, so that good results were obtained. However, in samples S10 and S11, the bubble content was too low, so that pinholes were generated in the single crystal. In addition, in sample S12, the bubble content of the corner portion was too high, so that dislocations had occurred, resulting in the deterioration of the pull-up yield.

Next, crucible samples S13, S14, and S15 were manufactured, which had different surface roughnesses by being subjected to different inner surface cleaning conditions after being manufactured under the same conditions as those of sample S9 described above. When the arithmetic average roughnesses Ra of the inner surfaces of samples S9, S13, S14, and S15 were measured, the arithmetic average roughness of sample S9 was Ra=0.01 μm, the arithmetic average roughness of sample S13 was Ra=0.1 μm, the arithmetic average roughness of sample S14 was Ra=0.2 μm, and the arithmetic average roughness of sample S15 was Ra=9 μm. Thereafter, as in sample S9, the pull-up yields and the presence or absence of pinholes in the silicon single crystal ingots of samples S13, S14, and S15 were evaluated.

As a result, as shown in Table 3, in samples S13 and S14, as in sample S9, the pull-up yield was good, and no pinhole defects were detected. On the other hand, in sample S15, although no pinhole defects were detected, dislocations had occurred in the single crystal, and the pull-up yield was degraded. It is considered that since the roughness of the inner surface of sample S15 is high, dislocations had occurred in the single crystal due to delamination of the inner surface.

TABLE 3

| Crucible sample | Pull-up yield | Pinhole |
|---|---|---|
| S9 | Good | Good |
| (Ra = 0.01 μm) | | |
| S13 | Good | Good |
| (Ra = 0.1 μm) | | |
| S14 | Good | Good |
| (Ra = 0.2 μm) | | |
| S15 | Poor | Good |
| (Ra = 9 μm) | | |

(Example 3: Evaluation Test of Bubble Size)

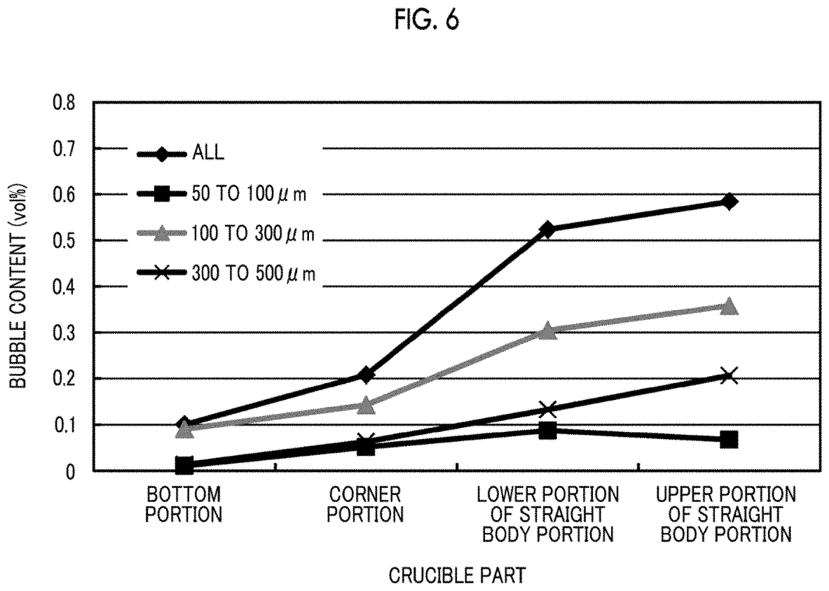

The correlation between the distribution of the bubble content and the bubble size of a quartz glass crucible having a diameter of 32 inches was evaluated. As a result, the bubble content of this quartz glass crucible was approximately 0% at the bottom portion, 0.12 to 0.21% at the corner portion, 0.21 to 0.52% at the lower portion of the straight body portion, and 0.32 to 0.59% at the upper portion of the straight body portion. The maximum value of the bubble content in each part of this crucible sample is shown in the graph of FIG. 6.

As shown in FIG. 6, it can be seen that although the proportion of the medium diameter sizes between 100 to 300 μm was largest at any measurement point regarding the bubble size, the proportion of the small diameter sizes (50 to 100 μm) with respect to the whole size was high and the proportion of the large diameter sizes (300 to 500 μm) was low at parts where the bubble content was low. Also, it can be seen that as the bubble content increases, the proportion of the small diameter size (50 to 100 μm) decreases, the proportion of the medium diameter size increases significantly, and the proportion of the large diameter size (300 to 500 μm) also increases. Therefore, by setting an appropriate bubble content for each part of the crucible, the average size of the bubbles can be optimized for each part of the crucible, whereby the effect of suppressing the generation of pinholes in the single crystal can be increased.

### EXPLANATION OF SYMBOLS

1 quartz glass crucible
1a straight body portion
1a₁ upper portion of straight body portion
1a₂ lower portion of straight body portion
1b bottom portion
1c corner portion
10a inner surface of crucible
10b outer surface of crucible
11 opaque layers
12 transparent layers
20 silicon single crystals
20a solid/liquid interface
21 silicon melt
21a melt surface

1. A quartz glass crucible comprising:
a straight body portion having a cylindrical shape;
a bottom portion which is curved; and
a corner portion provided between the straight body portion and the bottom portion,
wherein a bubble content of an inner surface layer portion ranging from an inner surface to a depth 0.5 mm in an upper portion of the straight body portion is 0.2% or more and 2% or less,
the bubble content of the inner surface layer portion in a lower portion of the straight body portion is more than 0.1% and not more than 1.3 times a lower limit of the bubble content of the upper portion of the straight body portion,
the bubble content of the inner surface layer portion in the corner portion is more than 0.1% and 0.5% or less, and
the bubble content of the inner surface layer portion in the bottom portion is 0.1% or less.

2. The quartz glass crucible according to claim 1,
wherein an average diameter of bubbles contained in the inner surface layer portion is 50 μm or more and 500 μm or less.
